(19) United States
(12) Patent Application Publication
(10) Pub. No.: US 2019/0177577 A1
(43) Pub. Date: Jun. 13, 2019

(54) ADHESIVE COMPOSITION FOR FLEXIBLE IMAGE DISPLAY DEVICES, ADHESIVE LAYER FOR FLEXIBLE IMAGE DISPLAY DEVICES, LAMINATE FOR FLEXIBLE IMAGE DISPLAY DEVICES, AND FLEXIBLE IMAGE DISPLAY DEVICE

(71) Applicant: NITTO DENKO CORPORATION, Ibaraki-shi, Osaka (JP)

(72) Inventors: Mizue Yamasaki, Ibaraki-shi (JP); Yusuke Toyama, Ibaraki-shi (JP); Yu Morimoto, Ibaraki-shi (JP)

(73) Assignee: NITTO DENKO CORPORATION, Ibaraki-shi, Osaka (JP)

(21) Appl. No.: 16/325,585

(22) PCT Filed: Aug. 2, 2017
(86) PCT No.: PCT/JP2017/028037

§ 371 Date: Feb. 14, 2019

(30) Foreign Application Priority Data
Aug. 15, 2016 (JP) 2016-159369

(51) Int. Cl. C09J 7/38; C09J 7/29; H01L 27/32; H01L 51/00; H01L 51/52; G06F 3/041

(52) U.S. Cl. CPC C09J 7/385; C09J 7/29; H01L 27/3244; H01L 27/323; H01L 51/0097; G06F 2203/04102; G06F 3/0412; C09J 2203/326; C09J 2433/00; H01L 2251/5338; H01L 51/5281

(57) ABSTRACT

The disclosure provides: a pressure-sensitive adhesive composition for a flexible image display device; a pressure-sensitive adhesive layer for a flexible image display device; a laminate for a flexible image display device, which, as a result of using the pressure-sensitive adhesive layer and au optical laminate, exhibits excellent bending resistance and adhesiveness, and does not peel even after repeated bending; and a flexible image display device. The pressure-sensitive adhesive composition includes a (meth)acrylic polymer including as monomer units: at least one monomer having a reactive functional group selected from the group consisting of hydroxyl group-containing monomers, carboxyl group-containing monomers, amino group-containing monomers, and amide group-containing monomers; and a (meth)acrylic monomer having a linear or branched alkyl group of 1 to 24 carbon atoms, wherein the monomer having the reactive functional group in all monomers constituting the (meth)acrylic polymer is 0.02 to 10% by weight.

### TECHNICAL FIELD

The present invention relates to a pressure-sensitive adhesive composition for a flexible image display device; a pressure-sensitive adhesive layer for a flexible image display device; a laminate for a flexible image display device including the pressure-sensitive adhesive layer and an optical laminate; and a flexible image display device in which the laminate for a flexible image display device is disposed.

As an organic EL display device integrated with a touch sensor is shown in FIG. 1, an optical laminate 20 is provided on the viewing side of an organic EL display panel 10, and a touch panel 30 is provided on the viewing side of the optical laminate 20. The optical laminate 20 includes a polarizer 1 having protective films 2-1 and 2-2 bonded on both sides thereof and a retardation film 3, and the polarizer 1 is provided on the viewing side of the retardation film 3. Further, in the touch panel 30, transparent conductive films 4-1 and 4-2 having a structure in which base material films 5-1 and 5-2 and transparent conductive layers 6-1 and 6-2 are laminated are disposed with a spacer 7 interposed therebetween (see, for example, Patent Document 1).

It is also expected to realize a foldable organic EL display device which is more excellent in portability.

### PRIOR ART DOCUMENT

### Patent Document

Patent Document 1: JP-A-2014-157745

### SUMMARY OF THE INVENTION

### Problems to be Solved by the Invention

However, the conventional organic EL display device as disclosed in Patent Document 1 is not designed with bending in mind. When a plastic film is used, for a base material of an organic EL display panel, bendability can be imparted to the organic EL display panel. In addition, even when the plastic film is used for a touch panel and incorporated in the organic EL display panel, bendability can be imparted to the organic EL display panel. However, a problem of hindering the bendability of the organic EL display device occurs due to an optical laminate formed by laminating a conventional polarizer, a protective film, thereof, and a retardation film on the organic EL display panel.

Accordingly, the purpose of the present invention is to provide: a pressure-sensitive adhesive composition for a flexible image display device, which contains a (meth)acrylic polymer formed from specific monomers; a pressure-sensitive adhesive layer for a flexible image display device, which is formed from the pressure-sensitive adhesive composition; a laminate for a flexible image display device, which, as a result of using the pressure-sensitive adhesive layer and an optical laminate, exhibits excellent bending resistance and adhesiveness, and does not peel even after repeated bending; and a flexible image display device in which the laminate for a flexible image display device is provided.

### Means for Solving the Problem

The pressure-sensitive adhesive composition for a flexible image display device of the present invention includes a (meth)acrylic polymer including as monomer units: at least, one monomer having a reactive functional group selected from the group consisting of hydroxyl group-containing monomers, carboxyl group-containing monomers, amino group-containing monomers, and amide group-containing monomers; and a (meth)acrylic monomer having a linear or branched alkyl group of 1 to 24 carbon atoms, wherein the monomer having the reactive functional group in all monomers constituting the (meth)acrylic polymer is 0.02 to 10% by weight.

The pressure-sensitive adhesive composition for a flexible image display device of the present invention preferably contains an isocyanate-based crosslinking agent and/or a peroxide-based crosslinking agent.

The pressure-sensitive adhesive layer for a flexible image display device of the present invention is a pressure-sensitive adhesive layer for a flexible image display device, which is formed from the pressure-sensitive adhesive composition, wherein a weight average molecular weight (Mw) of the (meth)acrylic polymer is preferably 1,000,000 to 2,500,000.

It is preferable that the laminate for a flexible image display device of the present invention is a laminate for a flexible image display device, comprising the pressure-sensitive adhesive layer for a flexible image display device and an optical laminate, wherein the pressure-sensitive adhesive layer for a flexible image display device is a first pressure-sensitive adhesive layer, the optical laminate includes a polarizer, a protective film of a transparent resin material on a first surface of the polarizer, and a retardation film on a second surface of the polarizer different from the first surface of the polarizer, and the first pressure-sensitive adhesive layer is disposed on a side opposite to the surface in contact with the polarizer with respect to the protective film.

In the laminate for a flexible image display device of the present invention, it is preferable that a second pressure-sensitive adhesive layer is disposed on the side opposite to the surface in contact with the polarizer with respect to the retardation film.

In the laminate for a flexible image display device of the present invention, it is preferable that a transparent conductive layer forming a touch sensor is disposed on the side opposite to the surface in contact with the retardation film with respect to the second pressure-sensitive adhesive layer.

In the laminate for a flexible image display device of the present invention, it is preferable that a third pressure-sensitive adhesive layer is disposed on the side opposite to the surface in contact with the second pressure-sensitive adhesive layer with respect to the transparent conductive layer forming a touch sensor.

In the laminate for a flexible image display device of the present invention, it is preferable that a transparent conductive layer forming a touch sensor is disposed on the side opposite to the surface in contact with the protective film with respect to the first pressure-sensitive adhesive layer.

In the laminate for a flexible image display device of the present invention, it is preferable that, a third pressure-sensitive adhesive layer is disposed on the side opposite to the surface in contact with the first pressure-sensitive adhesive layer with respect to the transparent conductive layer forming a touch sensor.

It is preferable that the flexible image display device of the present invention includes the laminate for a flexible image display device and an organic EL display panel, wherein the laminate for a flexible image display device is disposed on a viewing side with respect to the organic EL display panel.

In the flexible image display device of the present invention, it is preferable that a window is disposed on a viewing side with respect to the laminate for a flexible image display device.

### Effect of the Invention

The pressure-sensitive adhesive composition for a flexible image display device of the present invention contains a (meth)acrylic polymer composed of specific monomers, whereby the pressure-sensitive adhesive layer for a flexible image display device, formed from the pressure-sensitive adhesive composition, becomes a pressure-sensitive adhesive layer which is difficult to harden and has excellent stress relaxation property, and by using the specific adhesive layer and an optical laminate, the pressure-sensitive adhesive layer for a flexible image display device does not peel off even after repeated bending and can form a laminate for a flexible image display device excellent in bending resistance and adhesiveness, and it is possible to obtain a flexible image display device in which the laminate for a flexible image display device is disposed, which is useful.

Embodiments of a pressure-sensitive adhesive composition for a flexible image display device, a pressure-sensitive adhesive layer for a flexible image display device, a laminate for a flexible image display device, and a flexible image display device according to the present invention will be described in detail below with reference to the drawings and the like.

### BRIEF DESCRIPTION OF THE DRAWINGS

FIG. 1 is a cross-sectional view showing a conventional organic EL display device.

FIG. 2 is a cross-sectional view showing a flexible image display device according to an embodiment of the present invention.

FIG. 3 is a cross-sectional view showing a flexible image display device according to another embodiment of the present invention.

FIG. 4 is a cross-sectional view showing a flexible image display device according to another embodiment of the present invention.

FIG. 5 is a view showing a method for measuring folding endurance.

FIG. 6 is a cross-sectional view showing a sample for evaluation used in examples (Constitution A).

FIG. 7 is a cross-sectional view showing a sample for evaluation used in examples (Constitution B).

FIG. 8 is a view showing a method of producing a retardation used in examples.

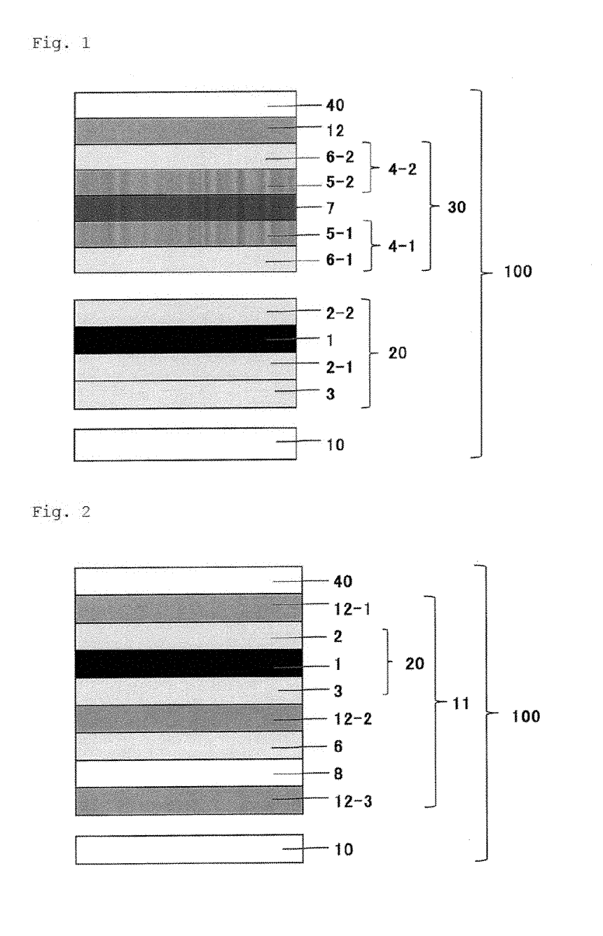

### MODE FOR CARRYING OUT THE INVENTION

### [Laminate for a Flexible Image Display Device]

it is preferable that a laminate for a flexible image display device according to the present invention includes a pressure-sensitive adhesive layer for a flexible image display device and an optical laminate, wherein the pressure-sensitive adhesive layer for a flexible image display device is a first pressure-sensitive adhesive layer, the optical laminate includes a polarizer, a protective film of a transparent resin material on the first surface of the polarizer, and a retardation film on a second surface of the polarizer different from the first surface of the polarizer, and wherein the first pressure-sensitive adhesive layer is disposed on the side opposite to the surface in contact with the polarizer with respect to the protective film.

### [Optical Laminate]

The laminate for a flexible image display device of the present invention includes an optical laminate, wherein the optical laminate preferably includes a polarizer, a protective film of a transparent resin material on a first surface of the polarizer, and a retardation film on a second surface different from the first surface of the polarizer. Note that the optical laminate does not include a first pressure-sensitive adhesive layer and a second pressure-sensitive adhesive layer which will be described later.

The thickness of the optical laminate is preferably 100 μm or less, more preferably 60 μm or less, even more preferably 10 to 50 μm. Within the above range, a preferred embodiment is obtained without hindering the bending.

As long as the properties of the present invention are not impaired, a protective film may be bonded to at least one side of the polarizer with an adhesive layer (not shown in the drawing). An adhesive can be used for the adhesion treatment of the polarizer and the protective film. Examples of the adhesive include isocyanate-based adhesives, polyvinyl alcohol-based adhesives, gelatin-based adhesives, vinyl-based latex, aqueous-based polyester and the like. The adhesive is usually used as an adhesive made of an aqueous solution, and usually contains 0.5 to 60% by weight of a solid content. Besides the above, as an adhesive between the polarizer and the protective film, an ultraviolet curable adhesive, an electron beam-curable adhesive and the like can be mentioned. The adhesive for electron beam-curable type polarizer shows suitable adhesion property to the various protective films mentioned above. The adhesive used in the present invention may contain a metal compound filler. In the present invention, those obtained by laminating a polarizer and a protective film with an adhesive (layer) may be sometimes referred to as a polarizing film (polarizing plate).

### <Polarizer>

In the polarizer used in the optical laminate of the present invention, a polyvinyl alcohol (PVA)-based resin which is stretched by a stretching step such as an in-air stretching (dry stretching) or a stretching step in an aqueous boric acid and in which iodine is aligned can be used.

Typically, as a method for producing the polarizer, there is a production method including a step of dyeing a single layer body of a PVA-based resin and a step of stretching such a single layer body as described in JP-A-2004-341515 (a monolayer stretching method). In addition, as described in JP-A-51-069644, JP-A-2000-338329, JP-A-2001-343521, WO 2010/100917, JP-A-2012-073563, and JP-A-2011-2816, there is exemplified a production method including a step of stretching a PVA-based resin layer and a stretching resin base material in the state of a laminate and a step of dyeing the laminate. According to this production method, even when the PVA-based resin layer is thin, such resin layer can be stretched without inconveniences such as breakage due to stretching because the resin layer is supported by the stretching resin base material.

As the production method including a step of stretching in the state of a laminate and a step of dyeing the laminate, an air stretching (dry stretching) method as described in JP-A-51-069644, JP-A-2000-333329, or JP-A-2001-343521 is exemplified. From the viewpoint of being able to stretching to a high drawing ratio and improve the polarization performance, a production method including a step of stretching in an aqueous boric acid solution as described in WO 2010/100917 A and JP-A-2012-073563 is preferable, and a production method (two-step stretching method) including a step of performing an auxiliary in-air stretching before stretching in an aqueous boric acid solution as described in JP-A-2012-073563 is particularly preferable. In addition, as described in JP-A-2011-2816, a method of stretching a PVA-based resin layer and a stretching resin base material in a laminate state, excessively dyeing the PVA-based resin layer, and then decoloring the dyed resin layer (excess dyeing decolonization method) is also preferable. The polarizer used in the optical laminate of the present invention is made of the polyvinyl alcohol-based resin in which iodine is aligned as described above and can be formed by laminating the polyvinyl alcohol-based resin stretched by a two-step stretching method including an auxiliary in-air stretching and a stretching in an aqueous boric acid solution. The polarizer used in the optical laminate of the present invention is made of the polyvinyl alcohol-based resin in which iodine is aligned as described above and can be prepared by excessively dyeing a laminate of a stretched PVA-based resin layer and a resin base material for stretching, followed by decoloring.

The thickness of the polarizer used in the optical laminate of the present invention is preferably 12 μm or less, more preferably 9 μm or less, even more preferably 1 to 8 μm, particularly preferably 3 to 6 μm. Within the above range of the thickness of the polarizer, a preferred embodiment is obtained without hindering the bending.

### <Retardation Film>

As the retardation film that can be used in the optical laminate in the present invention, one obtained by stretching a polymer film or one obtained by aligning and fixing a liquid crystal material can be used. In this specification, the retardation film means a film having birefringence in the plane and/or thickness direction.

Examples of the retardation film may include an anti-reflection retardation film (see paragraphs [0221], [0222], and [0228] in JP-A-2012-133303), a viewing-angle compensating retardation film (see paragraphs [0225] and [0226] in JP-A-2012-133303), and a viewing-angle compensating obliquely-aligned retardation film (see paragraph [0227] in JP-A-2012-133303).

Any known retardation film substantially having any of the functions described above can be used irrespective of, for example, the retardation value, the arrangement angle, the three-dimensional birefringence index, whether or not a single layer or a multilayer, and other factors.

In the present specification, Re [550] represents an in-plane retardation value measured by using light having a wavelength of 550 nm at 23° C. Re [550] can be determined by an expression: Re [550]=(nx−ny)×d, wherein nx and ny represent the refractive indices of a film in the slow axis direction and the fast axis direction at the wavelength of 550 nm, respectively, and d (nm) represents the thickness of the film. The slow axis is the direction in which the in-plane refractive index is maximized.

The in-plane birefringence Δn which is nx−ny of the present invention is 0.002 to 0.2, preferably 0.0025 to 0.15.

The in-plane retardation value of the above-mentioned retardation film measured by using light having the wavelength of 550 nm at 23° C. (Re [550] ) is preferably greater than the in-plane retardation value measured by using light having a wavelength of 450 nm. (Re [450]). Any retardation film having the wavelength dispersion characteristic and having the ratio that falls within the range described above can manifest a greater amount of retardation at a longer wavelength and can provide an ideal retardation characteristic at each wavelength in the visible region. For example, in a case the retardation film is used in an organic EL display, a circularly polarizing film or the like can be produced by producing a retardation film having the wavelength dependency described above as a quarter wavelength plate and bonding the retardation film to a polarizing film, whereby a neutral polarizing film and display device having a small degree of dependence of hue on a wavelength can be achieved. On the other hand, when the ratio does not fall within the range, the dependence of hue of reflected light on a wavelength increases, undesirably resulting in coloration of the polarizing film and the display device.

The ratio between Re [550] and Re [450] (Re [450]/Re [550]) of the retardation film is 0.8 or more and less than 1.0, more preferably 0.8 to 0.95.

The in-plane retardation value of the retardation film measured by using light having the wavelength of 550 nm at 23° C. (Re [550] ) is preferably smaller than the in-plane retardation value measured by using light having a wavelength of 650 nm (Re [650]). Any retardation film having the wavelength dispersion characteristic described above provides a constant retardation value in the red region. For example, in a case where the retardation film is used in a liquid crystal display device, a phenomenon in which light leakage occurs depending on the viewing angle and a phenomenon in which a displayed image becomes reddish (also called reddish phenomenon) can be remedied.

The ratio between Re [650] and Re [550] (Re [550]/Re [650]) of the retardation film described above is 0.8 or more and less than 1.0, more preferably 0.8 to 0.97. When Re [550]/Re [650] falls within any of the ranges described above, in a case where the retardation film is used, for example, in an organic EL display, more excellent display characteristics can be obtained.

Re [450], Re [550], and Re [650] can be measured by using “AxoScan” (product name) manufactured by Axometrics, Inc.

In the present specification, NZ (also called Nz coefficient) refers to the ratio between nx−nz which is the birefringence in the thickness direction and nx−ny which is the in-plane birefringence.

The NZ of the retardation film of the present invention is 0 to 1.3, preferably 0 to 1.25, more preferably 0 to 1.2.

The refractive index anisotropy of the retardation film of the present invention preferably satisfies the relationship of nx>ny, preferably nx>ny≥nz.

For example, in normal longitudinal stretching, a film is stretched in the longitudinal direction but is not fixed in the width direction, widthwise contraction occurs. The molecules in the film are more uniaxially aligned, and the refractive indices satisfy, for example, nx>ny=nz. In this case, the folding endurance of the film in the longitudinal direction thereof, which is the stretching direction, increases, whereas the folding endurance in the width direction greatly decreases. To solve the problem, the film is stretched in a state in which force for restricting the width is exerted on the film in an angular direction that intersects the stretching direction (for example, in lateral uniaxial stretching, force is so exerted on the film as to achieve a constant length in the longitudinal direction of the film, which is perpendicular to the width direction of the film, which is the stretching direction), whereby the molecules in the film can be aligned not only in the stretching direction but also in the angular direction that intersects the stretching direction, and the refractive indices can satisfy nx>ny>nz. High-level folding endurance in both the stretching direction and the width direction, can therefore be achieved.

The absolute value of the photoelastic coefficient C (m²/N) of the retardation film described above at 23° C. ranges from 2×10⁻¹² to 100×10⁻¹² (m²/N), preferably from 2×10⁻¹² to 50×10⁻¹² (m²/N). It can prevent a change in the retardation value caused by force acting on the retardation film due to contraction stress in the polarizer, heat generated by a display panel, and a surrounding environment (humidity resistance, heat resistance). As a result, a display panel device having satisfactory display uniformity can be provided. C of the retardation film described above preferably ranges from 3×10⁻¹² to 45×10⁻¹², particularly preferably from 10×10⁻¹² to 40×10⁻¹². Setting C to fall within any of the ranges described above allows reduction in the change and unevenness in the retardation value resulting from force acting on the retardation film described above. Further, a tradeoff relationship between the photoelastic coefficient and Δn tends to occur, and the photoelastic coefficient that falls within any of the ranges described above allows display quality to be maintained with no decrease in degree of retardation manifestation.

In one embodiment, the retardation film according to the present invention is produced by stretching a polymer film to align therein.

As a method for stretching the polymer film described above, any appropriate stretching method may be employed in accordance with the purpose. Examples of the stretching method appropriate for the present invention may include a lateral uniaxial stretching method, a longitudinal/lateral simultaneous biaxial stretching method, and a longitudinal/lateral successive biaxial stretching method. Examples of stretching means may include a tenter stretcher, a biaxial stretcher, or any other appropriate stretcher. The stretcher preferably includes a temperature control means. When a film is stretched while heated, the internal temperature in the stretcher may be continuously changed or intermittently changed. The stretching step may be carried out once or may be divided into two or more steps. The stretching direction is preferably a film width direction (TD direction) or an oblique direction.

In the oblique stretching, an oblique stretching process is continuously carried out as follows. An unstretched resin film is stretched in a direction inclining with respect to the width direction of the film by an angle that falls within the specific range described above with the film fed in the longitudinal direction. Thereby, an elongated retardation film can be so produced that the angle between the width direction and the slow axis direction of the film (alignment angle θ) falls within the specific range described above.

The method for performing oblique stretching is not limited to a specific method and may be any method that allows an unstretched resin film to be continuously stretched in a direction inclining with respect to the width direction of the film by an angle that falls within the specific range described above to form a slow axis in the direction inclining with respect to the width direction of the film by the angle that falls within the specific range. An appropriate stretching method may be adopted from conventionally known stretching methods described in, for example, JP-A-2005-319660, JP-A-2007-30466, JP-A-2014-194482, and JP-A-2014-199483.

An appropriate temperature (stretching temperature) at which an unstretched resin film is stretched may be selected as appropriate in accordance with the purpose. The stretching is preferably performed on a polymer film, with respect to the glass transition temperature (Tg) of the polymer film, at a temperature in a range from Tg −20° C. to Tg +30° C. When the condition described above is employed, a uniform retardation value is likely to be achieved, and the film is unlikely to be crystallized (clouded). Specifically, the stretching temperature described above preferably ranges from 90 to 210° C., more preferably from 100 to 200° C., particularly preferably from 100 to 180° C. The glass transition temperature can be determined by using a DSC method according to JIS K7121 (1987).

As a means for controlling the stretching temperature, any appropriate means may be employed. Examples of the temperature control means may include an air circulating, constant-temperature oven in which hot or cold air circulates, a heater using microwaves or far infrared radiation, and a roll, a heat pipe roll, and a metal belt that are heated for temperature control.

The draw ratio at which the unstretched resin film is stretched (stretch ratio) may be selected as appropriate in accordance with the purpose. The stretch ratio is preferably greater than 1 but smaller than or equal to 6, more preferably greater than 1.5 but smaller than or equal to 4.

Further, the film feed speed at the time of stretching is not limited to a specific value and preferably ranges from 0.5 to 30 m/min, more preferably from 1 to 20 m/min from viewpoints of mechanical precision, stability, and other factors. Under the stretching conditions, it is possible not only to obtain intended optical characteristics but also to obtain a retardation film excellent in optical uniformity.

In addition, as another embodiment, a retardation film formed as follows may be used: polycycloolefin films, polycarbonate films, or the like are bonded in sheet form to each other with an acrylic pressure-sensitive adhesive in such a way that the angle between the absorption axis of a polarizing film and the slow axis of a half wavelength plate is 15° and the angle between the absorption axis of the polarizing film and the slow axis of a quarter wavelength plate is 75°.

In another embodiment, the retardation film according to the present invention may be a laminate of retardation layers produced by aligning and fixing a liquid crystal material. Each of the retardation layers may be an alignment fixed layer of liquid crystal compound. Since use of a liquid crystal compound allows the difference between nx and ny of the resultant retardation layer to significantly increase as compared with the difference in a non-liquid-crystal material, the thickness of a retardation layer for providing desired in-plane retardation can be significantly reduced. As a result, the thickness of the circularly polarizing film (eventually, flexible image display device) can be further reduced. In the present specification, the “alignment fixed layer” refers to a layer in which liquid crystal compound is aligned in a predetermined direction and the alignment state is fixed. In the present embodiment, typically rod-like liquid crystal compounds are aligned in a state of being aligned in the slow axis direction of the retardation layer (homogeneous alignment). Examples of the liquid crystal compound include a liquid crystal compound (nematic liquid crystal) in which the liquid crystal phase is a nematic phase. As such a liquid crystal compound, for example, a liquid crystal polymer or a liquid crystal monomer can be used. The mechanism in accordance with which the liquid crystal property of the liquid crystal compound manifests may be the lyotropic or thermotropic mechanism. A liquid crystal polymer and a liquid crystal monomer may be used alone or in combination.

In the case where the liquid crystal compound is a liquid crystal monomer, the liquid crystal monomer is preferably a polymerizable monomer and a cross-linkable monomer. This is because the alignment state of the liquid crystal monomer can be fixed by polymerizing or crosslinking the liquid crystal monomer. After the liquid crystal monomer is aligned, the liquid crystal monomer is, for example, polymerized or cross-linked, whereby the alignment state can be fixed. At this point, the liquid crystal monomer is polymerized to form a polymer, and the liquid crystal monomer is cross-linked to form a three-dimensional network structure, but such structure is non-liquid crystalline. Therefore, for example, the formed retardation layer does not undergo transition to a liquid crystal phase, a glass phase, or a crystal phase due to a temperature change peculiar to the liquid crystalline compound. As a result, the retardation layer is changed to an extremely stable retardation layer that is not affected by a change in temperature.

The temperature range in which the liquid crystal monomer exhibits liquid crystallinity varies depending on the type of the liquid crystal monomer. Specifically, the temperature range is preferably 40 to 120° C., more preferably 50 to 100° C., and most preferably 60 to 90° C.

As the liquid crystal monomers, any appropriate liquid crystal monomer may be employed. For example, polymerizable mesogenic compounds described, for example, in JP-A-2002-533742 (WO 00/37585), EP 358208 (U.S. Pat. No. 5,211,877), EP 66137 (U.S. Pat. No. 4,388,453), WO 93/22397, EP 0261712, DE 19504224, DE 4408171, and GB 2280445, can be used. Specific examples of the polymerizable mesogenic compound may include LC242 (product name) manufactured by BASF, E7 (product, name) manufactured by Merck KGaA, and LC-Silicon-CC3767 (product name) manufactured by Wacker-Chem AG. The liquid crystal monomer is preferably, for example, a nematic liquid crystal monomer.

The alignment fixed layer of the liquid crystal compound may be formed by performing an alignment treatment on a surface of a predetermined base material, coating the surface with a coating liquid containing a liquid crystal compound to align the liquid crystal compound in the direction corresponding to the alignment treatment, and fixing the alignment state. In one embodiment, the base material may be any appropriate resin film, and the alignment fixed layer formed on the base material may be transferred onto a surface of the polarizer. At this point, the alignment fixed layer is so disposed that the angle between the absorption axis of the polarizer and the slow axis of the liquid crystal aligned and fixed layer is 15°. The retardation of the liquid crystal alignment fixed layer is λ/2 of the wavelength of 550 nm (about 270 nm). Further, a liquid crystal alignment fixed layer having a retardation of λ/4 of the wavelength of 550 nm (about 140 nm) is formed on the transferable base material in the same manner described above and so layered on the side of the half wavelength plate of the laminate of the polarizer and the half wavelength plate that the angle between the absorption axis of the polarizer and the slow axis of the quarter wavelength plate is 75°.

As the alignment treatment described above, any appropriate alignment treatment may be employed. Specifically, a mechanical alignment treatment, a physical alignment treatment, and a chemical alignment treatment may be listed as candidates of the alignment treatment. Specific examples of the mechanical alignment treatment may include a rubbing treatment and a stretching treatment. Specific examples of the physical alignment treatment may include a magnetic field alignment treatment and an electric field alignment treatment. Specific examples of the chemical alignment treatment may include an oblique evaporation method and an optical alignment treatment. Treatment conditions under which each of the alignment treatments is performed may be any appropriate conditions in accordance with the purpose.

The alignment of the liquid crystal compound is performed by treating the liquid crystal compound at a temperature at which the liquid crystal compound shows a liquid phase in accordance with the type of the liquid crystal compound. Such thermal treatment allows the liquid crystal compound to act in the liquid crystal state and the liquid crystal compound to be aligned in accordance with the direction in which the alignment treatment has been performed on the surface of the base material.

The alignment state is fixed in one embodiment by cooling the liquid crystal compound aligned as described above. In the case where, the liquid crystal compound is a polymerizable monomer or a cross-linkable monomer, the alignment state is fixed by performing polymerization or cross-linkage on the liquid crystal compound aligned as described above.

Specific examples of the liquid crystal compound and the method of forming the alignment fixed layer are described in detail in JP-A-2006-163343. The description of the publication is hereby incorporated by reference.

The thickness of the retardation film used in the optical laminate of the present invention is preferably 20 μm or less, more preferably 10 μm or less, even more preferably 1 to 9 μm, particularly preferably 3 to 8 μm. Within the above range, a preferred embodiment is obtained without hindering the bending.

### <Protective Film>

As the protective film (also referred to as a transparent protective film) of the transparent resin material used for the optical laminate of the present invention, a cycloolefin-based resin such as a norbornene resin, an olefin-based resin such as polyethylene and polypropylene, a polyester-based resin, a (meth)acrylic resin or the like can be used.

The thickness of the protective film used with the optical laminate according to the present invention ranges of preferably 5 to 60 μm, more preferably 10 to 40 μm, even more preferably 10 to 30 μm, and a surface treatment layer, such as an anti-glare layer or an antireflection layer, may be provided as appropriate. Within the above range, a preferred embodiment is obtained without hindering the bending.

### [First Pressure-Sensitive Adhesive Layer]

The first pressure-sensitive adhesive layer used in the laminate for a flexible image display device of the present invention is preferably disposed on the side opposite to the surface in contact with the polarizer with respect to the protective film.

The pressure-sensitive adhesive layer forming the first pressure-sensitive adhesive layer used in the laminate for a flexible image display device of the present invention is formed from a pressure-sensitive adhesive composition for a flexible image display device, the pressure-sensitive adhesive composition containing a (meth)acrylic polymer including, as monomer units: at least one monomer having a reactive functional group selected from the group consisting of hydroxyl group-containing monomers, carboxyl group-containing monomers, amino group-containing monomers, and amide group-containing monomers; and a (meth)acrylic monomer having a linear or branched alkyl group of 1 to 24 carbon atoms, wherein the monomer having the reactive functional group in all monomers constituting the (meth)acrylic polymer is 0.02 to 10% by weight. Incidentally, the pressure-sensitive adhesive (composition) forming the pressure-sensitive adhesive layer uses an acrylic pressure-sensitive adhesive containing the (meth)acrylic polymer, but a rubber-based pressure-sensitive adhesive, a vinyl alkyl ether-based pressure-sensitive adhesive, a silicone-based pressure-sensitive adhesive, a polyester-based pressure-sensitive adhesive, a polyamide-based pressure-sensitive adhesive, a urethane-based pressure-sensitive adhesive, a fluorine-based pressure-sensitive adhesive, an epoxy-based pressure-sensitive adhesive, or a polyether-based pressure-sensitive adhesive can be used in combination, as long as it does not affect the characteristics of the present invention. However, from the viewpoints of transparency, processability, durability, adhesiveness, bending resistance, etc., it is preferable to use an acrylic pressure-sensitive adhesive alone.

### <(Meth)acrylic Polymer>

The pressure-sensitive adhesive composition contains a (meth)acrylic polymer containing a (meth)acrylic monomer having a linear or branched alkyl group of 1 to 24 carbon atoms as a monomer unit. By using the (meth)acrylic monomer having a linear or branched alkyl group of 1 to 24 carbon atoms, a pressure-sensitive adhesive layer excellent in bendability can be obtained. In the present invention, the term “(meth)acrylic polymer” refers to an acrylic polymer and/or a methacrylic polymer, and the term “(meth)acrylate” refers to an acrylate and/or a methacrylate.

Specific examples of the (meth)acrylic monomer having a linear or branched alkyl group of 1 to 24 carbon atoms forming the main skeleton of the (meth)acrylic polymer include methyl (meth)acrylate, ethyl (meth)acrylate, n-butyl (meth)acrylate, s-butyl (meth)acrylate, t-butyl (meth)acrylate, isobutyl (meth)acrylate, n-pentyl (meth)acrylate, isopentyl (meth)acrylate, n-hexyl (meth)acrylate, isohexyl (meth)acrylate, isoheptyl (meth)acrylate, 2-ethylhexyl (meth)acrylate, n-octyl (meth)acrylate, isooctyl (meth)acrylate, n-nonyl (meth)acrylate, isononyl (meth)acrylate, n-decyl (meth)acrylate, isodecyl (meth)acrylate, n-dodecyl (meth)acrylate, n-tridecyl (meth)acrylate, n-tetradecyl (meth)acrylate, etc. Among them, a monomer having a low glass transition temperature (Tg) generally becomes a viscoelastic body even in a high-speed region at the time of bending, so from the viewpoint of bendability, (meth)acrylic monomer having a linear or branched alkyl group of 4 to 8 carbon atoms is preferred. As the (meth) acrylic monomer, one or two or more monomers can be used.

The (meth)acrylic monomer having a linear or branched alkyl group of 1 to 24 carbon atoms is a main component in all the monomers forming the (meth)acrylic polymer. Here, as the main component, the total amount of (meth)acrylic monomer having a linear or branched alkyl group of 1 to 24 carbon atoms in all the monomers constituting the (meth)acrylic polymer is preferably 70 to 100% by weight, more preferably from 80 to 99.9% by weight, even more preferably from 85 to 99.9% by weight, particularly preferably from 90 to 99.8% by weight.

The pressure-sensitive adhesive composition contains, as monomer units, at least one monomer having a reactive functional group selected from the group consisting of a hydroxyl group-containing monomer, a carboxyl group-containing monomer, an amino group-containing monomer, and an amide group-containing monomer,

wherein the monomer having the reactive functional group in all monomers constituting the (meth)acrylic polymer is preferably 0.02 to 10% by weight, more preferably 0.05 to 7% by weight, even more preferably 0.2 to 3% by weight of all monomers forming the (meth)acrylic polymer. When the amount of the monomer having the reactive functional group is reduced to 0.02 to 10% by weight, the crosslinking point is reduced, and a pressure-sensitive adhesive layer which is hard to harden and has an excellent stress relaxation property can be obtained. When the amount of such monomer exceeds 10% by weight, the number of crosslinking points increases, so that the crosslinking density becomes larger and bendability becomes poorer. In particular, at the time of bending under moist heat test, the shrinkage stress of the polarizing film cannot be alleviated, and breakage occurs. If the amount of such monomer is less than 0.02% by weight, since the reaction point with the film is small, the adhesion is lowered, and peeling is likely to occur particularly at the time of bending under moist heat test. Among these monomers, hydroxyl group-containing monomers are particularly preferable because of good balance between bendability and peeling. As the monomer having the reactive functional group, one or two or more kinds of the monomers can be used.

The hydroxyl group-containing monomer contains a hydroxyl group in its structure and is a compound containing a polymerizable unsaturated double bond such as a (meth)acryloyl group and a vinyl group.

The hydroxyl group-containing monomer is a compound containing a hydroxyl group and a polymerizable unsaturated double bond such as a (meth)acryloyl group or a vinyl group in its structure. Specific examples of the hydroxyl group-containing monomer include hydroxyalkyl (meth)acrylates such as 2-hydroxyethyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, etc. and 4-hydroxymethylcyclohexyl)-methyl acrylate. Among the hydroxyl group-containing monomers, 2-hydroxyethyl (meth)acrylate and 4-hydroxybutyl (meth)acrylate are preferable from the viewpoints of peeling and bendability at the time of bending under moist heating, and 4-hydroxybutyl (meth)acrylate is particularly preferred.

As the carboxyl group-containing monomer, those having a polymerizable functional group having an unsaturated double bond such as a (meth)acryloyl group or a vinyl group and having a carboxyl group can be used without particular limitation. Examples of the carboxyl group-containing monomer include (meth)acrylic acid, carboxyethyl (meth)acrylate, carboxypentyl (meth)acrylate, itaconic acid, maleic acid, fumaric acid, crotonic acid, isocrotonic acid, and the like, and these can be used alone or in combination. Itaconic acid and maleic acid my be used in the form of anhydrides. Among them, acrylic acid and methacrylic acid are preferably used, and acrylic acid is particularly preferable in view of effectively suppressing peeling during a moist heat testing.

The amino group-containing monomer having a polymerizable functional group having an unsaturated double bond such as a (meth)acryloyl group or a vinyl group and having an amino group can be used without any particular limitation. Examples of the amino group-containing monomer include aminoethyl (meth)acrylate, N,N-dimethylaminoethyl (meth)acrylate, N,N-dimethylaminopropyl (meth)acrylate, and the like.

The amide group-containing monomer is a compound containing an amide group in its structure and containing a polymerizable unsaturated double bond such as a (meth)acryloyl group or a vinyl group. Specific examples of the amide group-containing monomer include acrylamide-based monomers such as (meth)acrylamide, N,N-dimethyl (meth)acrylamide, N,N-diethyl (meth)acrylamide, N-isopropylacrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers such as N-(meth)acryloyl morpholine, N-(meth)acryloyl piperidine, and N-(meth)acryloyl pyrrolidine; N-vinyl group-containing lactam monomers such as N-vinylpyrrolidone and N-vinyl-ε-caprolactam; and the like.

In the pressure-sensitive adhesive composition, it is preferable that the (meth)acrylic polymer contains, as the monomer units, only butyl acrylate which is the (meth)acrylic monomer having a linear or branched alkyl group of 1 to 24 carbon atoms, and 4-hydroxybutyl acrylate which is the hydroxyl group-containing monomer.

As the monomer unit forming the (meth)acrylic polymer, in addition to the monomer having a reactive functional group, other copolymerizable monomers can be introduced as long as the effect of the present invention is not impaired. The blending ratio of such copolymerizable monomer is not particularly limited but is preferably 30% by weight or less in all the monomers forming the (meth)acrylic polymer, and more preferably, such other copolymerizable monomers are not contained in the monomer unit for forming the (meth)acrylic polymer. When the blending ratio of the other copolymerizable monomers exceeds 30% by weight, in particular when a material other than the (meth)acrylic monomer is used, the reaction point with the film tends to be small and the adhesion tends to decrease.

In the present invention, when the (meth)acrylic polymer is used, such polymer usually has a weight average molecular weight (Mw) in the range of 1,000,000 to 2,500,000. In consideration of durability, particularly heat resistance and bendability, the weight average molecular weight is preferably from 1,200,000 to 2,200,000, more preferably from 1,400,000 to 2,000,000 . When the weight average molecular weight is smaller than 1,000,000, at the time of crosslinking the polymer chains with each other in order to ensure durability, the number of crosslinking points is increased to lose the flexibility of the pressure-sensitive adhesive (layer), compared with those having a weight average molecular weight of 1,000,000 or more, and as a result, the dimensional change of the outer bend side (convex side) and the inner bend side (concave side) occurring between the films at the time of bending cannot be alleviated, and the film tends to break easily. In addition, when the weight average molecular weight exceeds 2,500,000, a large amount of a diluting solvent is required for adjusting the viscosity for coating, which undesirably leads to an increase in cost, and since the entanglement of the polymer chains of the resulting (meth)acrylic polymer becomes complicated, breakage of the film is likely to occur at the time of bending. The weight average molecular weight (Mw) is a value calculated in terms of polystyrene as measured by GPC (gel permeation chromatography).

Such a (meth)acrylic polymer may be produced by a method selected appropriately from known production methods such as solution polymerization, bulk polymerization, emulsion polymerization and various radical polymerizations. The resultant (meth)acrylic polymer may be any one of random copolymers, block copolymers, graft copolymers, and the like.

In the solution polymerization, as a polymerization solvent, for example, ethyl acetate, toluene, or the like is used. In a specific example of the solution polymerization, a reaction is performed in the presence of a polymerization initiator in an inert gas, such as nitrogen, ordinarily under the reaction conditions of a temperature of about 50 to 70° C. and a period of about 5 to 30 hours.

A polymerization initiator, a chain transfer agent, an emulsifier and others that are used in the radical polymerizations are not particularly limited and may be used after appropriate selection. The weight average molecular weight of the (meth)acrylic polymer is controllable in accordance with the respective use amounts of the polymerization initiator and the chain transfer agent, and the reaction conditions. The amount of use thereof is appropriately adjusted according to the kind of these substances

Examples of the polymerization initiator include, but are not limited to, azo initiators such as 2,2′-azobisisobutylonitrile, 2,2″-azobis(2-amidinopropane)dihydrochloride, 2,2′-azobis[2-(5-methyl-2-imidazolin-2-yl)propane]dihydrochloride, 2,2′-azobis(2-methylpropionamidine)disulfate, 2,2′-azobis(N,N′-dimethyleneisobutylamidine), and 2,2′-azobis[N-(2-carboxyethyl)-2-methylpropionamidine]hydrate (VA-057, manufactured by Wako Pure Chemical Industries, Ltd.); persulfates such as potassium persulfate and ammonium persulfate; peroxide-based initiators such as di(2-ethylhexyl)peroxydicarbonate, di(4-tert-butylcyclohexyl) peroxydicarbonate, di-sec-butyl peroxydicarbonate, tert-butyl peroxyneodecanoate, tert-hexyl peroxypivalate, tert-butyl peroxypivalate, dilauroyl peroxide, di-n-octanoyl peroxide, 1,1,3,3-tetramethylbutyl peroxy-2-ethylhexanoate, di(4-methylbenzoyl) peroxide, dibenzoyl peroxide, tert-butyl peroxyisobutylate, 1,1-di(tert-hexylperoxy) cyclohexane, tert-butyl hydroperoxide, and hydrogen peroxide; and redox system initiators of a combination of a peroxide and a reducing agent, such as a combination of a persulfate and sodium hydrogen sulfite and a combination of a peroxide and sodium ascorbate.

One of the above polymerization initiators may be used alone, or two or more thereof may be used in a mixture. The total content of the polymerization initiator is preferably from about 0.005 to 1 part by weight, more preferably from about 0.02 to about 0.5 parts by weight, per 100 parts by weight of all the monomers forming the (meth)acrylic polymer.

In the case of using a chain transfer agent, an emulsifier used for emulsion polymerization, or a reactive emulsifier, conventionally known ones can be appropriately used. In addition, these addition amounts can be appropriately determined within a range not to impair the effect of the present invention.

### <Crosslinking Agent>

The pressure-sensitive adhesive composition of the present invention may contain a cross linking agent. An organic crosslinking agent or a polyfunctional metal chelate may be used as the crosslinking agent. Examples of the organic crosslinking agent include an isocyanate-based crosslinking agent, a peroxide-based crosslinking agent, an epoxy-based crosslinking agent, an imine-based crosslinking agent, and the like. The polyfunctional metal chelate may include those in which a polyvalent metal is covalently or coordinately bonded to an organic compound. Examples of the polyvalent metal atom include Al, Cr, Zr, Co, Cu, Fe, Ni, V, Zn, In, Ca, Mg, Mn, Y, Ce, Sr, Ba, Mo, La, Sn, and Ti. Examples of the atom in the organic compound that is covalently or coordinately bonded include an oxygen atom and the like. Examples of the organic compound include alkyl esters, alcohol compounds, carboxylic acid compounds, ether compounds, ketone compounds, and the like. Among them, it is preferable to contain an isocyanate-based cross linking agent and/or a peroxide-based crosslinking agent, and in particular, an isocyanate-based crosslinking agent (particularly, a trifunctional isocyanate-based crosslinking agent) is preferable from the viewpoint of durability. In addition, a peroxide-based crosslinking agent and an isocyanate-based crosslinking agent (particularly, a bifunctional isocyanate-based crosslinking agent) are preferable from the viewpoint of bendability. Both the peroxide-based crosslinking agent and the bifunctional isocyanate-based crosslinking agent form a flexible two-dimensional crosslinking, whereas the trifunctional isocyanate-based crosslinking agent forms a stronger three-dimensional crosslinking. When bending, two-dimensional crosslinking, which is a more flexible crosslinking, is advantageous. However, since only two-dimensional crosslinking is poor in durability and peeling is likely to occur, hybrid crosslinking between two-dimensional crosslinking and three-dimensional crosslinking is favorable, so that a trifunctional isocyanate-based crosslinking agent and a peroxide-based crosslinking agent or a bifunctional isocyanate-based crosslinking agent are preferably used in combination.

The amount of the crosslinking agent to be used is preferably 0.01 to 5 parts by weight, more preferably 0.03 to 2 parts by weight, even more preferably less than 0.03 to 1 part by weight, per 100 parts by weight of the (meth)acrylic polymer. Within the above range, a preferred embodiment excellent in bending resistance is obtained.

### <Other Additives>

Further, the pressure-sensitive adhesive composition of the present invention may contain any other known additives, including, for example, various silane coupling agents, polyether compounds such as polyalkylene glycol (e.g. polypropylene glycol etc.), powder such as coloring agents and pigments, dyes, surfactants, plasticizers, tackifiers, surface lubricants, leveling agents, softeners, antioxidants, anti-ageing agents, light stabilizers, ultraviolet absorbers, polymerization inhibitors, antistatic agents (alkali metal salt or ionic liquid which are an ionic compound, etc.), inorganic or organic fillers, metal powder, particle- or foil-shaped materials, and the like, and such additives can be appropriately added depending on the intended use. In addition, a redox system including a reducing agent to be added may also be used in the controllable range.

### [Other Pressure-Sensitive Adhesive Layer]

The second pressure-sensitive adhesive layer used in the laminate for a flexible image display device of the present invention can be disposed on the side opposite to the surface in contact with the polarizer with respect to the retardation film.

The third pressure-sensitive adhesive layer used in the laminate for a flexible image display device of the present invention can be disposed on the side opposite to the surface in contact with the second pressure-sensitive adhesive layer with respect to the transparent conductive layer forming a touch sensor.

The third pressure-sensitive adhesive layer used in the laminate for a flexible image display device of the present invention can be disposed on the side opposite to the surface in contact with the first pressure-sensitive adhesive layer with respect to the transparent conductive layer forming a touch sensor.

In the case of using the second pressure-sensitive, adhesive layer and further other adhesive layer (for example, third pressure-sensitive adhesive layer or the like) in addition to the first pressure-sensitive adhesive layer, these pressure-sensitive adhesive layers may have the same composition (same pressure-sensitive adhesive composition), may have the same characteristics, or may have different characteristics, but are not particularly limited. From the viewpoints of workability, economy, and bendability, it is preferable that all the pressure-sensitive adhesive layers are each a pressure-sensitive adhesive layer having substantially the same composition and the same characteristics.

### <Formation of Pressure-Sensitive Adhesive Layer>

The pressure-sensitive adhesive layer in the present invention is preferably formed from the pressure-sensitive adhesive composition. For example, the pressure-sensitive adhesive layer may be formed by a method including applying the pressure-sensitive adhesive composition to a release-treated separator or the like, removing the polymerization solvent and the like by drying to form a pressure-sensitive adhesive layer, or by a method including applying the pressure-sensitive adhesive composition to a polarizing film or the like, and removing the polymerization solvent and the like by drying to form a pressure-sensitive adhesive layer on the polarizing film or the like. In applying the pressure-sensitive adhesive composition, one or more kinds of solvents other than the polymerization solvent may be newly added as needed.

A silicone release liner is preferably used as the release-treated separator. When the pressure-sensitive adhesive composition of the present invention is applied to such a liner and dried to form a pressure-sensitive adhesive layer, any appropriate drying method may be suitably adopted depending on the purpose. A method of drying under heating is preferably used. The heat drying temperature is preferably from 40° C. to 200° C., more preferably from 50° C. to 180° C., particularly preferably from 70° C. to 170° C. When the heating temperature is set in the above range, a pressure-sensitive adhesive layer having good adhesive property can be obtained.

Any suitable drying time may be used as appropriate. The drying time is preferably from 5 seconds to 20 minutes, more preferably from 5 seconds to 10 minutes, particularly preferably from 10 seconds to 5 minutes.

As a coating method of the pressure-sensitive adhesive composition, various methods may be used. Specific examples of such methods include a roll, coating method, a kiss roll coating method, a gravure coating method, a reverse coating method, a roll brush coating method, a spray coating method, a dip roll coating method, a bar coating method, a knife coating method, an air knife coating method, a curtain coating method, a lip coating method, and an extrusion coating method with a die coater or the like.

The thickness of the pressure-sensitive adhesive layer used in the laminate for a flexible image display device of the present invention is preferably 1 to 200 μm, more preferably 5 to 150 μm, even more preferably 15 to 100 μm. The pressure-sensitive adhesive layer may be a single layer or may have a laminated structure. A preferred embodiment is within the above range in terms of not inhibiting the bending and also in terms of adhesiveness (retention resistance). Further, in the case of having a plurality of pressure-sensitive adhesive layers, all the pressure-sensitive adhesive layers are preferably within the above-mentioned range. If the thickness of the pressure-sensitive adhesive layer exceeds 200 μm, polymer chains in the pressure-sensitive adhesive layer are easy to move and such pressure-sensitive adhesive tends to be exhausted during repetitive bending, resulting in the occurrence of easy peeling. In the case of the thickness less than 1 μm, the stress at the time of bending cannot be relaxed, and breakage tends to occur.

The storage elastic modulus (G′) of the pressure-sensitive adhesive layer used in the laminate for a flexible image display device of the present invention at 25° C. is preferably 1.0 MPa or less, more preferably 0.8 MPa or less, even more preferably 0.3 MPa or less at 25° C. When the storage elastic modulus of the pressure-sensitive adhesive layer is in such a range, it is difficult for the pressure-sensitive adhesive layer to become hard, and such a pressure-sensitive adhesive layer is excellent in stress relaxation property and excellent in bending resistance, so that it is possible to realize a bendable or foldable flexible image display device.

The upper limit of the glass transition temperature (Tg) of the pressure-sensitive adhesive layer used in the laminate for a flexible image display device of the present invention is preferably 0° C. or less, more preferably −20° C. or less, even more preferably −25° C. or less, particularly preferably −30° C. or less. The lower limit of Tg is preferably −50° C. or more, more preferably −45° C. or more. When the Tg of the pressure-sensitive adhesive layer is in such a range, it is difficult to harden the pressure-sensitive adhesive layer even in a high-speed region at the time of bending, so that a flexible image display device which is excellent in stress relaxation property and is bendable or foldable can be realized.

The total light transmittance (according to JIS K7136). in the visible light wavelength region of the pressure-sensitive adhesive layer for a flexible image display device of the present invention is preferably 85% or more, more preferably 90% or more.

The haze (according to JIS K7136) of the pressure-sensitive adhesive layer for a flexible image display device of the present invention is preferably 3.0% or less, more preferably 2.0% or less.

Incidentally, the total light transmittance and the haze can be measured using, for example, a haze meter (trade name “HM-150” manufactured by Murakami Color Research Laboratory).

### [Transparent Conductive Layer]

A member having a transparent conductive layer is not particularly limited and known materials can be used as such a member. The member includes those having a transparent conductive layer on a transparent base material such as a transparent film or the like and a member having a transparent conductive layer and a liquid crystal cell can be mentioned.

The transparent base material may be of any type having transparency, and examples thereof include a base material (for example, a sheet-like, film-like, or plate-like base material) made of a resin film or the like. The thickness of the transparent base material is not particularly limited, but is preferably about 10 to 200 μm, more preferably about 15 to 150 μm.

The resin film may be made of any material, such as any of various plastic materials having transparency. Examples of such materials include polyester-based resins such as polyethylene terephthalate and polyethylene naphthalate, acetate-based resins, polyethersulfone-based resins, polycarbonate-based resins, polyamide-based resins, polyimide-based resins, polyolefin-based resins, (meth)acrylic resins, polyvinyl chloride-based resins, polyvinylidene chloride-based resins, polystyrene-based resins, polyvinyl alcohol-based resins, polyarylate-based resins, and polyphenylene sulfide-based resins. Among them, polyester-based resins, polyimide-based resins, and polyethersulfone-based resins are particularly preferred.

The surface of the transparent base material may be previously subjected to sputtering, corona discharge treatment, flame treatment, ultraviolet irradiation, electron beam irradiation, chemical treatment, etching treatment such as oxidation, or under coating treatment so that the transparent base material can have improved adhesiveness to the transparent conductive layer formed thereon. Before the transparent conductive layer is formed, if necessary, the transparent base material may be subjected to solvent washing or ultrasonic washing for removal of dust and cleaning.

Examples of the material used to form the transparent conductive layer include, but not limited to, metal oxides of at least a metal selected from the group consisting of indium, tin, zinc, gallium, antimony, titanium, silicon, zirconium, magnesium, aluminum, gold, silver, copper, palladium, and tungsten. If necessary, the metal oxides may be doped with any metal from the group shown above. For example, tin oxide-doped indium oxide (ITO) and antimony-doped tin oxide are preferably used, and in particular, ITO is preferably used. ITO preferably includes 80 to 99% by weight of indium oxide and 1 to 20% by weight of tin oxide.

The ITO may be crystalline or amorphous. The crystalline ITO can be obtained by high-temperature sputtering or further heating an amorphous ITO.

The thickness of the transparent conductive layer of the present invention is preferably 0.005 to 10 μm, more preferably 0.01 to 3 μm, even more preferably 0.01 to 1 μm. When the thickness of the transparent conductive layer is less than 0.005 μm, the transparent conductive layer tends to be more variable in electric resistance. On the other hand, the transparent conductive layer with a thickness of more than 10 μm may be produced with lower productivity at higher cost and tend to have a lower level of optical properties.

The total light transmittance of the transparent conductive layer of the present invention is preferably 80% or more, more preferably 85% or more, even more preferably 90% or more.

The density of the transparent conductive layer of the present invention is preferably 1.0 to 10.5 g/cm³, more preferably 1.3 to 3.0 g/cm³.

The surface resistance value of the transparent conductive layer of the present invention is preferably 0.1 to 1000 Ω/□, more preferably 0.5 to 500 Ω/□, even more preferably 1 to 250 Ω/□.

The method for forming the transparent conductive layer is not particularly limited, and conventionally known methods can be adopted. Specifically, for example, a vacuum deposition method, a sputtering method, and an ion plating method can be exemplified. In addition, an appropriate method can be adopted according to the required film thickness.

In addition, an undercoat layer, an oligomer prevention layer, and the like can be provided between the transparent conductive layer and the transparent base material, if necessary.

The transparent conductive layer forms a touch sensor and is required to be configured to be bendable.

The transparent conductive layer forming a touch sensor used in the laminate for a flexible image display device of the present invention may be disposed on the side opposite to the surface in contact with the retardation film with respect to the second pressure-sensitive adhesive layer.

The transparent conductive layer forming a touch sensor used in the laminate for a flexible image display device of the present invention may be disposed on the side opposite to the surface in contact with the protective film with respect to the first pressure-sensitive adhesive layer.

The transparent conductive layer forming a touch sensor used for the laminate for a flexible image display device of the present invention may be disposed between the protective film and a window film (OCA).

In addition, the transparent conductive layer can be suitably applied to a liquid crystal display device incorporating a touch sensor such as an in-cell type or an on-cell type as a case of being used for a flexible image display device, and in particular, a touch sensor may be built in (even incorporated) in an organic EL display panel.

### [Conductive Layer (Antistatic Layer)]

Further, the laminate for a flexible image display device of the present invention may have a layer having conductivity (a conductive layer, an antistatic layer). Since the laminate for a flexible image display device has a bending function and has a very thin thickness structure, such a laminate is highly responsive to feeble static electricity generated in a manufacturing process or the like and is easily damaged, but by providing a conductive layer in the laminate, the load due to static electricity in the manufacturing process and the like is largely reduced, which is a preferable embodiment.

In addition, one of the major features of the flexible image display device including the laminate is to have a bending function, but in the case of continuous bending, static electricity may be generated due to shrinkage between the films (base material) at the bent portion. Therefore, when conductivity is imparted to the laminate, generated static electricity can be promptly removed and damage caused by static electricity of the image display device can be reduced, which is a preferable embodiment.

Further, the conductive layer may be an undercoat layer having a conductive function, a pressure-sensitive adhesive containing a conductive component, or a surface treatment layer containing a conductive component. For example, a method of forming a conductive layer between a polarizing film and a pressure-sensitive adhesive layer by using an antistatic composition containing a binder and a conductive polymer such as polythiophene can be employed. Further, a pressure-sensitive adhesive containing an ionic compound which is an antistatic agent can also be used. The conductive layer preferably has one or more layers and may contain two or more layers.

### [Flexible Image Display Device]

The flexible image display device of the present invention includes the laminate for a flexible image display device and an organic EL display panel configured to be foldable, wherein the laminate for a flexible image display device is disposed on a viewing side and configured to be foldable with respect, to the organic EL display panel. Although arbitrary, a window can be disposed on the viewing side with respect to the laminate for a flexible image display device.

FIG. 2 is a cross-sectional view showing one embodiment of a flexible image display device according to the present invention. A flexible image display device 100 includes a laminate 11 for the flexible image display device and an organic EL display panel 10 configured to be foldable. The laminate 11 for the flexible image display device is disposed on the viewing side with respect to the organic EL display panel 10, and the flexible image display device 100 is configured to be foldable. Further, although optional, a transparent window 40 can be disposed on the viewing side of the laminate for the flexible image display device with an interposed first pressure-sensitive adhesive layer 12-1 with respect to the laminate 11 for the flexible image display device.

The laminate 11 for the flexible image display device includes the optical laminate 20 and the pressure-sensitive adhesive layer forming a second pressure-sensitive adhesive layer 12-2 and a third pressure-sensitive adhesive layer 12-3.

The optical laminate 20 includes a polarizer 1, a protective film 2 made of a transparent resin material, and a retardation film 3. The protective film 2 made of a transparent resin material is bonded to a first surface on the viewing side of the polarizer 1. The retardation film 3 is bonded to a second surface different from the first surface of the polarizer 1. For example, the polarizer 1 and the retardation film 3 generate circularly polarized light in order to prevent light incident inside from the viewing side of the polarizer 1 from being internally reflected and emitted to the viewing side, or to compensate a viewing angle.

In the present embodiment, a protective film is provided on one side of a polarizer only, whereas a protective film is conventionally provided on both sides of a polarizer, and the thickness of the optical laminate 20 can be reduced by using a polarizer having a very thin thickness (for example, 20 μm or less) as compared with the polarizer used in the conventional organic EL display device. In addition, since the polarizer 1 is much thinner than the polarizer used in the conventional organic EL display device, stress due to expansion and contraction occurring under temperature or humidity conditions becomes extremely smaller. Therefore, the possibility that the stress caused by the shrinkage of the polarizer causes deformation such as warping in the adjacent organic EL display panel 10 is greatly reduced, and the deterioration of the display quality due to deformation and breakage of the panel sealing material can be greatly suppressed. In addition, by using a thin polarizer, bending is not hindered, which is a preferable embodiment.

In the case of bending the optical laminate 20 with the protective film 2 side as the inside, the thickness (for example, 92 μm or less) of the optical laminate 20 is thinned and the first pressure-sensitive adhesive layer 12-1 having the storage elastic modulus as described above is disposed on the side opposite to the retardation film 3 with respect to the protective film 2 to make it possible to reduce the stress applied to the optical laminate 20, whereby the optical laminate 20 can be folded. Therefore, an appropriate range of the storage elastic modulus may be set according to the environmental temperature in which the flexible image display device is used. For example, in the case where the assumed use environment temperature is from −20° C. to +85° C., it is possible to use a first pressure-sensitive adhesive layer such that the storage elastic modulus at 25° C. falls within an appropriate numerical range.

Optionally, a foldable transparent conductive layer 6 forming a touch sensor may further be disposed on the side opposite to the protective film 2 with respect to the retardation film 3. The transparent conductive layer 6 is configured to be directly bonded to the retardation film 3 by a manufacturing method as disclosed in, for example, JP-A-2014-219667, whereby the thickness of the optical laminate 20 is reduced and the stress applied to the optical laminate 20 when the optical laminate 20 is folded can be further reduced.

Optionally, a pressure-sensitive adhesive layer forming a third pressure-sensitive adhesive layer 12-3 can be further disposed on the side opposite to the retardation film 3 with respect to the transparent conductive layer 6. In the present embodiment, the second pressure-sensitive adhesive layer 12-2 is directly bonded to the transparent conductive layer 6. By providing the second pressure-sensitive adhesive layer 12-2, it is possible to further reduce the stress applied to the optical laminate 20 when folded.

The flexible image display device shown in FIG. 3 is substantially the same as that shown in FIG. 2. In the flexible image display device of FIG. 2, a foldable transparent conductive layer 6 forming a touch sensor is disposed on the side opposite to the protective film 2 with respect to the retardation film 3, whereas in the flexible linage display device of FIG. 3, a foldable transparent conductive layer 6 forming a touch sensor is disposed on the side opposite to the protective film 2 with respect to the first pressure-sensitive adhesive layer 12-1. This is a different point. Further, there is a different point in that in the flexible image display device of FIG. 2, the third pressure-sensitive adhesive layer 12-3 is disposed on the side opposite to the retardation film 3 with respect to the transparent conductive layer 2, whereas in the flexible image display device of FIG. 3, the second pressure-sensitive adhesive layer 12-2 is disposed on the side opposite to the protective film 2 with respect to the retardation film 3.

In addition, although optional, the third pressure-sensitive adhesive layer 12-3 can be disposed when the window 40 is disposed on the viewing side with respect to the laminate 11 for the flexible image display device.

The flexible image display device of the present invention can be suitably used as a flexible liquid crystal display device, an organic EL (electroluminescence) display device, a PDF (plasma display panel), and an electronic paper. Further, such a flexible image display device can be used irrespective of a type of a touch panel or the like such as a resistive film type or a capacitive type.

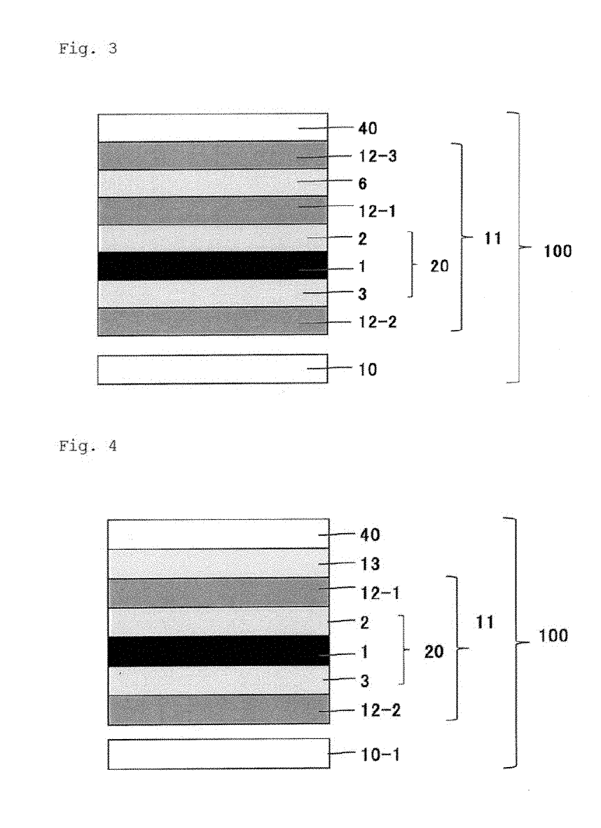

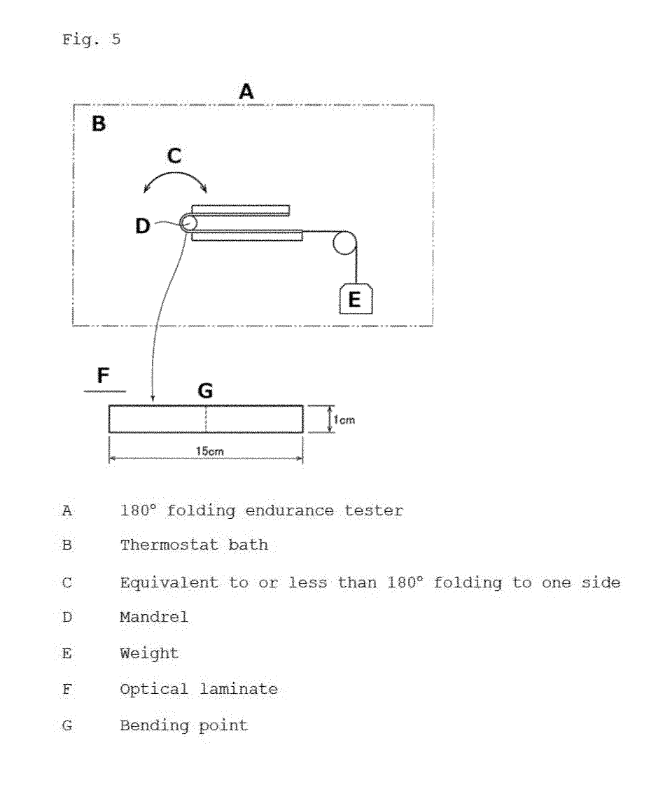

In addition, as shown in FIG. 4, the flexible image display device of the present invention may also be used as an in-cell type flexible image display device in which the transparent conductive layer 6 forming a touch sensor is incorporated in the organic EL display panel 10.

### EXAMPLES

Several examples relating to the present invention will be described below, but the present invention is not intended to be limited to such specific examples. In addition, the numerical values in tables are blending amounts (addition amounts) and showed solid contents or solid fractions (weight basis). The contents of the formulation and the evaluation results are shown in Tables 1 to 4.

### Example 1

### [Polarizer]

An amorphous polyethylene terephthalate (hereinafter referred to as “PET”) (IPA-copolymerized PET) film (thickness: 100 μm) with 7 mol % of isophthalic acid unit was used as a thermoplastic resin base material, and a surface of the film was subjected to a corona treatment (58 W/m²/min).

Further, a PVA (polymerization degree: 4200, saponification degree: 99.2%) added with 1 wt % of acetoacetyl-modified PVA (trade name; Gohsefimer 2200 (average polymerization degree: 1200, saponification degree: 98.5 mol %, acetoacetyl-modification degree: 5 mol %), manufactured by Nippon Synthetic Chemical Industry Co., Ltd.) was used to preliminarily prepare a coating solution consisting of an aqueous PVA solution containing 5.5 wt % of PVA-based resin. Then, the coating solution was applied onto a base material to allow a film thickness after drying to become 12 μm and subjected to hot-air drying under an atmosphere at 60° C. for 10 minutes to prepare a laminate in which a layer of the PVA-based resin is provided on the base material.

Then, this laminate was first subjected to free-end stretching in air (auxiliary in-air stretching) at 130° C. at a stretching ratio of 1.8 times to form a stretched laminate.

Then, the stretched laminate was immersed in a boric acid insolubilizing aqueous solution having a temperature of 30° C. for 30 seconds to perform a step of insolubilizing a PVA layer in which PVA molecules are aligned and which is contained in the stretched laminate. The boric acid insolubilizing aqueous solution in this step was prepared to allow a boric acid to be contained in an amount of 3 weight parts with respect to 100 weight parts of water. The stretched laminate was subjected to dyeing to form a dyed laminate. The dyed laminate was prepared by immersing the stretched laminate in a dyeing solution containing iodine and potassium iodide and having a temperature of 30° C. for an arbitrary time, in such a manner that a single layer transmittance of a PVA layer making up a polarizer to be finally obtained falls with the range of 40 to 44%, thereby causing the PVA layer included in the stretched laminate to be dyed with iodine. In this step, the dyeing solution was prepared using water as a solvent to allow an iodine concentration and a potassium iodide concentration to fall with the range of 0.1 to 0.4% by weight, and the range of 0.7 to 2.8% by weight, respectively. A concentration ratio of iodine to potassium iodide was 1:7. Then a step of immersing the dyed laminate in a boric acid crosslinking aqueous solution at 30° C. for 60 seconds so as to subject PVA molecules in the PVA layer having iodine adsorbed therein to a cross-linking treatment was performed. The boric acid crosslinking aqueous solution in this step was set to contain boric acid in an amount of 3 weight parts with respect to 100 parts by weight of water and contain potassium iodide in an amount of 3 parts by weight with respect to 100 parts by weight of water.

Further, an obtained dyed laminate was stretched in an aqueous boric acid solution (stretching in an aqueous boric acid solution) at a stretching temperature of 70° C., at a stretching ratio of 3.05 times in the same direction as that during the previous in-air stretching to obtain an optical film laminate stretched at a final (total) stretching ratio of 5.50 times. The optical film laminate was taken out of the aqueous boric acid solution, and a boric acid attaching on a surface of the PVA layer was washed with an aqueous solution containing 4 parts by weight of potassium iodide with respect to 100 pars by weight, of water. The washed optical film laminate was dried through a drying step using hot air at 60° C. The polarizer included the obtained optical film laminate had a thickness of 5 μm.

### [Protective Film]

A protective film obtained by extruding a methacrylic resin pellet having a glutarimide ring unit to form a film shape and then stretching the film was used. This protective film had a thickness of 20 μm and was an acrylic film having a moisture permeability of 160 g/m².

Next, the polarizer and the protective film were bonded using an adhesive shown below to obtain a polarizing film.

As the adhesive (active energy ray-curable adhesive), each component was mixed according to the formulation table shown in Table 1 and stirred at 50° C. for 1 hour to prepare an adhesive (active energy ray-curable adhesive A). Numerical values in tire table indicate weight % when the total amount of the composition is taken as 100% by weight. Each component used is as follows.

HEAA: Hydroxyethylacrylamide

M-220: ARONIX M-220, tripropylene glycol diacrylate) manufactured by Toagosei Co., Ltd.

ACMO: Acryloyl morpholine

AAEM: 2-Acetoacetoxyethyl methacrylate, manufactured by The Nippon Synthetic Chemical Industry Co., Ltd.

UP-1190: ARUFON UP-1190, manufactured by Toagosei Co., Ltd.

IRG 907: IRGACURE 907, 2-methyl-1-(4-methylthiophenyl)-2-morpholinopropan-1-one, manufactured by BASF

DETX-S: KAYACURE DETX-S, diethylthioxanthone, manufactured by Nippon Kayaku Co., Ltd.

TABLE 1

| | Adhesive |
|---|---|
| (wt %) | composition |
| HEAA | 11.4 |
| M-220 | 57.1 |
| ACMO | 11.4 |
| AAEM | 4.6 |
| UP-1190 | 11.4 |
| IRG 907 | 2.8 |
| DETX-S | 1.3 |

In examples and comparative examples using the adhesive, alter the protective film and the polarizer were laminated with the interposed adhesive, the adhesive was cured by irradiation with ultraviolet light to form an adhesive layer. For irradiation with ultraviolet rays, a gallium-encapsulated metal halide lamp (trade name “Light HAMMER 10” manufactured by Fusion UV Systems, Inc., bulb: V bulb, peak illuminance: 1600 mW/cm², integrated irradiation amount: 1000/mJ/cm² (wavelength 380 to 440 nm)) was used.

### [Retardation Film]

The retardation film (a quarter wavelength retardation plate) of this example was a retardation film composed of two layers of a retardation layer for a quarter wavelength plate and a retardation layer for a half wavelength plate, in which a liquid crystal material is aligned and fixed. Specifically, such retardation film was manufactured as follows.

### (Liquid Crystal Material)

A polymerizable liquid crystal material (trade name: Paliocolor LC242, manufactured by BASF) showing a nematic liquid crystal phase was used as a material for forming a retardation layer for a half wavelength plate and a retardation layer for a quarter wavelength plate. A photopolymerization initiator (trade name Irgacure 907, manufactured by BASF) for the polymerizable liquid crystal material was dissolved in toluene. Further, for the purpose of improving the coating property, a MEGAFACE series manufactured by DIC was added in an amount of about 0.1 to 0.5% according to the liquid crystal thickness to prepare a liquid crystal coating solution. The liquid crystal coating solution was applied on an alignment base material with a bar coater, dried by heating at 90° C. for 2 minutes, and subjected to alignment fixation by ultraviolet curing under a nitrogen atmosphere. As the base material, for example, one capable of transferring the liquid crystal coating layer later, such as PET, was used. Further, for the purpose of improving coatability, a fluorine-based polymer which is a MEGAFACE series made by DIC Corporation was added in an amount of about 0.1% to 0.5% depending on the thickness of the liquid crystal layer, and MIBK (methyl isobutyl ketone), cyclohexanone, or a mixed solvent of MIBK and cyclohexanone was used to dissolve the polymer to a solid content concentration of 25%, thereby to prepare a coating solution. This coating solution was applied on a base material with a wire bar, dried at 65° C. for 3 minutes, and subjected to alignment fixation by ultraviolet curing under a nitrogen atmosphere to perform the preparation. As the base material, for example, one capable of transferring the liquid crystal coating layer later, such as PET, was used.

### (Manufacturing Process)

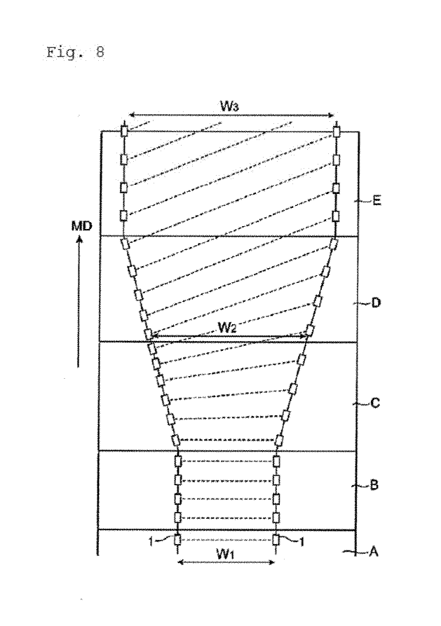

The manufacturing process of the present embodiment will be described with reference to FIG. 8. The numbers in FIG. 8 are different from the numbers in other drawings. In this manufacturing process 20, a base material 14 was provided by a roll, and this base material 14 was supplied from a supply reel 21. In the manufacturing process 20, a coating solution of an ultraviolet curable resin 10 was applied to the base material 14 by a die 22. In the manufacturing process 20, a roll plate 30 was a cylindrical shaping mold in which a concavo-convex shape relating to an alignment film for a quarter wavelength plate of a quarter wavelength retardation plate was formed on the peripheral side surface. In the manufacturing process 20, the base material 14 coated with the ultraviolet curable resin is pressed against the circumferential side surface of the roll plate 30 by a pressure roller 24, and the ultraviolet curable resin was irradiated with ultraviolet light by an ultraviolet irradiation device 25 composed of a high-pressure mercury lamp and then cured. As a result, in the manufacturing process 20, the concavo-convex shape formed on the peripheral side surface of the roll plate 30 was transferred to the base material 14 so as to be at 75° with respect to the MD direction. Thereafter, the base material 14 integrally with the cured ultraviolet curable resin 10 was peeled from the roll plate 30 by a peeling roller 26, and the liquid crystal material was applied by a die 29. After that, the liquid crystal material was cured by irradiation with ultraviolet rays by an ultraviolet irradiation device 27, whereby a configuration relating to the retardation layer for a quarter wavelength plate was formed.

Subsequently, in this step 20, the base material 14 is conveyed to a die 32 by a conveying roller 31, and the coating solution of an ultraviolet curing resin 12 is applied onto the retardation layer for a quarter wavelength plate of the base material 14 by the die 32. In this manufacturing process 20, a roll plate 40 was a cylindrical shaping mold in which a concavo-convex shape relating to the alignment film for a half wavelength plate of the quarter wavelength retardation plate was formed on the circumferential side surface. In the manufacturing process 20, the base material 14 coated with the ultraviolet curing resin was pressed against the peripheral side surface of the roll plate 40 by a pressure roller 34, and the ultraviolet curable resin was irradiated with ultraviolet rays by an ultraviolet irradiation device 35 composed of a high-pressure mercury lamp, and then cured. As a result, in the manufacturing process 20, the concavo-convex shape formed on the circumferential side surface of the roll plate 40 was transferred onto the base material 14 so as to be at 15° with respect to the MD direction. Thereafter, the base material 14 integrally with the cared ultraviolet curable resin 12 was peeled from the roll plate 40 by a peeling roller 36, and the liquid crystal material was applied thereon by a die 39. After that, the liquid crystal material was cured by irradiation with ultraviolet rays by an ultraviolet irradiation device 37, whereby a configuration relating to the retardation layer for a half wavelength plate was obtained. Thus, a retardation film having a thickness of 7 μm and composed of two layers of a retardation layer for a quarter wavelength plate and a retardation layer for a half wavelength plate was obtained.

### [Optical Film (Optical Laminate)]

The retardation film obtained as described above and the polarizing film obtained as described above were continuously laminated by the roll-to-roll method using the adhesive to prepare a laminated film (optical laminate) so that an axis angle became 45° between the slow axis and the absorption axis.

Subsequently, the obtained laminated film (optical laminate) was cut into 15 cm×5 cm.

### <Preparation of (Meth)acrylic Polymer A1>

A monomer mixture containing 99 parts by weight of butyl acrylate (BA) and 1 part toy weight of 4-hydroxybutyl acrylate (HBA) was charged into a four-necked flask equipped with a stirring blade, a thermometer, a nitrogen gas inlet tube and a condenser.

Further, 0.1 parts by weight of 2,2′-azobisisobutyronitrile as a polymerization initiator together with ethyl acetate were added to 100 parts by weight of the monomer mixture (solid content), and nitrogen gas was introduced thereto with gentle stirring. After nitrogen substitution, polymerization reaction was carried out for 7 hours while maintaining the liquid temperature in the flask at around 55° C. Thereafter, ethyl acetate was added to the obtained reaction solution to prepare a solution of a (meth)acrylic polymer A1 having a weight average molecular weight of 1,600,000 which was adjusted to have a solid content concentration of 30% by addition of ethyl acetate.

### <Preparation of Acrylic Pressure-Sensitive Adhesive Composition>

An acrylic pressure-sensitive adhesive composition was prepared by blending 0.1 parts by weight of an isocyanate-based crosslinking agent (trade name: TAKENATE D110N, trimethylolpropane xylylene diisocyanate, manufactured by Mitsui Chemicals, Inc.), 0.3 parts by weight of a peroxide-based crosslinking agent, benzoyl peroxide (trade name: NYPER BMT, manufactured by NOF Corporation), and 0.08 parts by weight of a silane coupling agent (trade name: KBM 403, manufactured by Shin-Etsu Chemical Co., Ltd.) with 100 parts by weight of the solid content of the obtained (meth)acrylic polymer A1 solution.

### <Preparation of Pressure-Sensitive Adhesive Layer Attached Optical Laminate>

The acrylic pressure-sensitive adhesive composition was uniformly applied to the surface of a polyethylene terephthalate film (PET film, transparent base material, separator) having a thickness of 38 μm treated with a silicone-based releasing agent using a fountain coater, and dried at 155° C. in an air circulation type thermostatic oven for 2 minutes to form a pressure-sensitive adhesive layer having a thickness of 25 μm on the surface of the base material.

Next, a separator having a pressure-sensitive adhesive layer formed thereon was transferred to the protective film side (corona-treated) of the obtained optical laminate to prepare a pressure-sensitive adhesive layer attached an optical laminate.

### <Laminate for Flexible Image Display Device>

As shown in FIG. 6, after peeling off the separator of the above resulting pressure-sensitive adhesive layer attached the optical laminate, a PET film having a thickness of 25 μm (transparent base material, manufactured by Mitsubishi Plastics Ltd., trade name: DIAFOIL) was laminated to the pressure-sensitive adhesive layer, thereby to prepare a laminate for a flexible image display device corresponding to the configuration A used in Example 1.

In the laminate for a flexible image display device corresponding to the configuration B, a separator having a pressure-sensitive adhesive layer formed thereon was transferred to the retardation film side (corona-treated) of the obtained optical laminate to prepare a pressure-sensitive adhesive layer attached an optical laminate.

Next, as shown in FIG. 7, after releasing the separator of the above resulting pressure-sensitive adhesive layer attached the optical laminate, a polyimide film having a thickness of 77 μm (PI film, KAPTON 300V, base material, manufactured by Du Pont-Toray Co., Ltd.) was laminated to the pressure-sensitive adhesive layer, thereby to prepare a laminate for a flexible image display device corresponding to the configuration B used in Example 8.

### <Preparation of (Meth)acrylic Polymers A4 and A5>

(Meth)acrylic polymers A4 and A5 were prepared in the same manner as the preparation of (meth)acrylic polymers A1, except that the polymerization, reaction was carried out with a mixing ratio (weight ratio) of ethyl acetate and toluene of 85/15 in the polymerization reaction for 7 hours while maintaining the liquid temperature in the flask at around 55° C.

### Examples 2 to 8 and Comparative Examples 1 and 2

In the preparation of the polymer ((meth)acrylic polymer) and the pressure-sensitive adhesive composition to be used in Example 1, a laminate for a flexible image display device was prepared in the same manner as in Example 1 except that each composition was changed as shown in Tables 2 to 4.

Abbreviations in Tables 2 and 3 are as follows.

BA: n-Butyl acrylate

2EHA: 2-Ethylhexyl acrylate

AA: Acrylic acid

HBA: 4-Hydroxybutyl acrylate

HEA: 2-Hydroxyethyl acrylate

MMA: Methyl methacrylate

NVP: N-Vinylpyrrolidone

D110N: Trimethylolpropane/xylylene diisocyanate adduct (trade name: TAKENATE D110N, manufactured by Mitsui Chemicals, Inc.)

D160N: Adduct of trimethylolpropane in hexamethylene diisocyanate (trade name: TAKENATE D160N, manufactured by Mitsui Chemicals, Inc.)

C/L: Trimethylolpropane/tolylene diisocyanate (trade name: CORONATE L, manufactured by Nippon Polyurethane Industry Co., Ltd.)

Peroxide: Benzoyl peroxide (peroxide-based crosslinking agent, manufactured by NOF Corporation, trade name: NYPER BMT)

### [Evaluation]

### <Measurement of Weight Average Molecular Weight (Mw) of (Meth)acrylic Polymer>

The weight average molecular weight (Mw) of the obtained (meth)acrylic polymer was measured by GPC (gel permeation chromatography).
Analyzer: HLC-8120 GPC, manufactured by Tosoh Corporation
Column: G7000H_{XL}+GMH_{XL}+GMH_{XL}, manufactured by Tosoh Corporation
Column size: each 7.8 mmϕ×30 cm, 90 cm in total
Column temperature: 40° C.
Flow rate: 0.8 ml/min
Injection volume: 100 μl
Eluent: Tetrahydrofuran
Detector: Differential refractometer (RI)
Standard sample: Polystyrene

### (Measurement of Thickness)

The thickness of each of the polarizer, the retardation film, the protective film, the optical laminate, and the pressure-sensitive adhesive layer was calculated together with measurement using a dial gauge (manufactured by Mitutoyo Corporation).

(Measurement of Glass Transition Temperature Tg of Pressure-Sensitive Adhesive layer)

The glass transition temperature (Tg) of the pressure-sensitive adhesive layer was obtained from the peak top temperature of tanδ obtained from a dynamic viscoelasticity measurement under the following measurement conditions using a dynamic viscoelasticity measuring device “RSA III” (trade name) manufactured by TA Instruments Co., Ltd.

### (Measurement Conditions)

Deformation mode: twisting

Measurement temperature: −40° C. to 150° C.

Rate of temperature increase: 5° C./min

### (Measurement of Glass Transition Temperature Tg of Pressure-Sensitive Adhesive Layer)

The separator was peeled off from the surface of the pressure-sensitive adhesive layer of each of examples and comparative examples, and a plurality of pressure-sensitive adhesive layers were laminated to prepare a test sample having a thickness of about 1.5 mm. This test sample was punched out into a disk shape with a diameter of 8 mm, sandwiched between parallel plates, and the glass transition temperature was obtained from the peak top temperature of tanδ obtained from a dynamic viscoelasticity measurement under the following measurement conditions using a dynamic viscoelasticity measuring device “RSA III” (trade name) manufactured by TA Instruments Co., Ltd.

### (Measurement Conditions)

Deformation mode: twisting
Measurement temperature: −40° C. to 150° C.
Rate of temperature increase: 5° C./min

### (Folding Endurance Test)

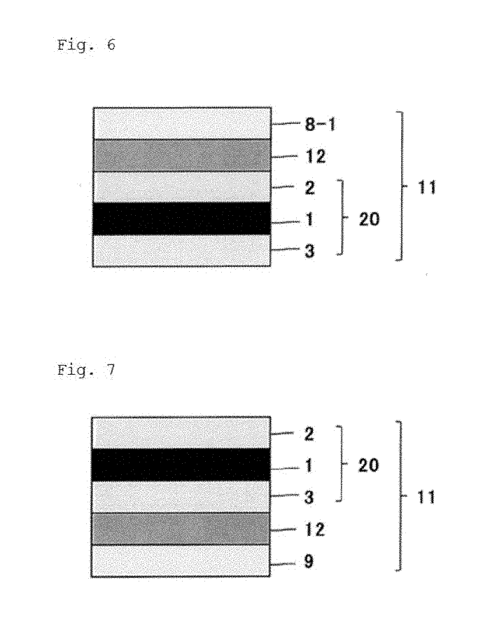

FIG. 5 is a schematic view of a 180° folding endurance tester (manufactured by Imoto Machinery Co., Ltd.). This tester has a mechanism in which a chuck on one side repeats 180° bending across a mandrel and is capable of changing a bending radius on the basis of the diameter of the mandrel. In the tester, the test is stopped when the film breaks. The laminate (5 cm×15 cm) for flexible image display device, obtained in each of examples and comparative examples, was set in the tester and the folding endurance test was performed under the conditions of a temperature of 60° C. and a humidity of 95% RH, a bending angle of 180°, a bending radius of 3 mm, a bending rate of 1 second/time, and a weight of 100 g. Folding endurance was evaluated on the basis of the number of times of folding until breakage of the laminate for a flexible image display device occurred. When the number of bending reached 200,000 times, the test was terminated.

### <Presence or Absence of Breakage>

5: Mo breakage was observed (practical use level).

4: A partial breakage was observed in only a part of the polarizing film (practical use level).

3: A slight breakage was observed in only a part of the polarizing film at the end of the bent portion (practical use level).

2: All layers of the polarizing film are slightly broken at the end of the bent portion (practical use level).

1: Breakage was observed on the entire surface of the bent portion (no practical use level).

### <Presence or Absence of Appearance Defects (Peeling)>

◯: Peeling was not observed (practical use level).

Δ: Slight peeling was observed at the bent portion (practical use level).

x: Peeling was observed at the entire bent portion (no practical use level).

TABLE 2

| | | | | | | | | Molecular | |
|---|---|---|---|---|---|---|---|---|---|
| (Meth) | | | | | | | | weight of | |
| acrylic | Composition | | | | | | | (meth)acrylic | |
| polymer | BA | 2EHA | AA | HBA | HEA | MMA | NVP | polymer | |
| A1 | 99 | | | 1 | | | | 1.6 | million |
| A2 | 98 | | 1 | 1 | | | | 1.6 | million |
| A3 | | 99.9 | | | 0.1 | | | 1.75 | million |
| A4 | 96 | | | 1 | | | 3 | 1.65 | million |
| A5 | 93 | | | 1 | | | 6 | 1.6 | million |
| A6 | | 63 | | | 13 | 9 | 15 | 1 | million |
| A7 | 97 | | | 3 | | | | 1.65 | million |
| A8 | 93 | | | 7 | | | | 1.8 | million |
| A9 | 99.99 | | | 0.01 | | | | 1.5 | million |

TABLE 3

| Formu- | | | | | | | |
|---|---|---|---|---|---|---|---|
| lation | (Meth)acrylic | | | | | | |
| of | polymer | | | | | | |
| pressure- | | Blend- | Crosslinking agent | | | | |
| sensitive | | ing | | | | Per- | Tg |
| adhesive | Kind | amount | D110N | D160N | C/L | oxide | [° C]. |
| 1 | A1 | 100 | 0.1 | | | 0.3 | −38 |
| 2 | A2 | 100 | | 0.15 | | 0.3 | −33 |
| 3 | A3 | 100 | | | 0.15 | | −40 |
| 4 | A4 | 100 | | 0.6 | | 0.3 | −33 |
| 5 | A5 | 100 | 0.1 | | | 0.3 | −29 |
| 6 | A6 | 100 | 1 | | | | 5 |
| 7 | A7 | 100 | 0.1 | | | 0.3 | −29 |
| 8 | A8 | 100 | 0.1 | | | 0.3 | −24 |
| 9 | A9 | 100 | 0.1 | | | 0.3 | −43 |

TABLE 4

| | | Thickness of | Kind of | | |
|---|---|---|---|---|---|
| | | pressure- | pressure- | Folding | |
| | | sensitive | sensitive | endurance test | |
| Evaluation | Config- | adhesive layer | adhesive | 60° C. × 95% | |
| results | uration | [μm] | layer | Breakage | Peeling |
| Example 1 | A | 25 | 1 | 5 | ◯ |
| Example 2 | A | 25 | 7 | 5 | ◯ |
| Example 3 | A | 25 | 2 | 4 | ◯ |
| Example 4 | A | 25 | 3 | 5 | Δ |
| Example 5 | A | 25 | 4 | 3 | ◯ |
| Example 6 | A | 25 | 8 | 3 | ◯ |
| Example 7 | A | 25 | 5 | 2 | ◯ |
| Example 8 | B | 25 | 1 | 5 | ◯ |
| Comparative | A | 25 | 6 | 1 | ◯ |
| example 1 | | | | | |
| Comparative | A | 25 | 9 | 5 | X |
| example 2 | | | | | |

From the evaluation results in Table 4, it was confirmed that the folding endurance was practically acceptable level in all the examples. That is, it was confirmed that by using a specific pressure-sensitive adhesive layer for the optical film including a polarizer, a protective film thereof, and a retardation film in the laminate for a flexible image display device in each example, a laminate for a flexible image display device, excellent in bending resistance and adhesiveness, can be obtained without peeling off even after repeated bending.

On the other hand, in Comparative Example 1, it was confirmed that since the blending ratio of the monomer having a reactive functional group exceeds the desired amount, the stress at the time of bending could not be relaxed, the film was broken, and the bendability was inferior. In Comparative Example 2, since the blending ratio of the monomer having a reactive functional group is small, it was confirmed that a pressure-sensitive adhesive capable of relaxing stress could be obtained and breakage did not occur, but the reactivity with the film was poor and peeling occurred during the bending test because the blending ratio of the monomer having a reactive functional group was less than the desired amount.

Although the present invention has been described with reference to the drawings concerning specific embodiments, the present invention can be modified in a number of ways other than the illustrated and described configurations. Accordingly, the present invention is not limited to the illustrated and described configurations, and the scope of the present invention is to be determined only by the appended claims and their equivalents.

### DESCRIPTION OF REFERENCE SIGNS

1 Polarizer

2. Protective film

2-1 Protective film

2-2 Protective film

3 Retardation layer

4-1 Transparent conductive film

4-2 Transparent conductive film

5-1 Base material film

5-2 Base material film

6 Transparent conductive layer

6-1 Transparent conductive layer

6-2 Transparent conductive layer

7 Spacer

8 Transparent base material

8-1 Transparent base material (PET film)

9 Base material (PI film)

10 Organic EL display panel

11 Laminate for flexible image display device (laminate for organic EL display device)

12 Pressure-sensitive adhesive layer

12-1 First pressure-sensitive adhesive layer

12-2 Second pressure-sensitive adhesive layer

12-3 Third pressure-sensitive adhesive layer

13 Decorative printing film

20 Optical laminate

30 Touch panel

40 Window

100 Flexible image display device (organic EL display device)

1. A pressure-sensitive adhesive composition for a flexible image display device, comprising a (meth)acrylic polymer including as monomer units:
at least one monomer having a reactive functional group selected from the group consisting of hydroxyl group-containing monomers, carboxyl group-containing monomers, amino group-containing monomers, and amide group-containing monomers; and
a (meth)acrylic monomer having a linear or branched alkyl group of 1 to 24 carbon atoms,
wherein the monomer having the reactive functional group in all monomers constituting the (meth)acrylic polymer is 0.02 to 10% by weight.

2. The pressure-sensitive adhesive composition for a flexible image display device according to claim 1, which contains an isocyanate-based crosslinking agent and/or a peroxide-based crosslinking agent.

3. A pressure-sensitive adhesive layer for a flexible image display device, which is formed from the pressure-sensitive adhesive composition according to claim 1, wherein a weight average molecular weight (Mw) of the (meth)acrylic polymer is from 1,000,000 to 2,500,000.

4. A laminate for a flexible image display device, comprising the pressure-sensitive adhesive layer for a flexible image display device according to claim 3 and an optical laminate, wherein
the pressure-sensitive adhesive layer for a flexible image display device is a first pressure-sensitive adhesive layer,
the optical laminate includes a polarizer, a protective film of a transparent resin material on a first surface of the polarizer, and a retardation film on a second surface of the polarizer different from the first surface of the polarizer, and
the first pressure-sensitive adhesive layer is disposed on a side opposite to the surface in contact with the polarizer with respect to the protective film.

5. The laminate for a flexible image display device according to claim 4, wherein a second pressure-sensitive adhesive layer is disposed on the side opposite to the surface in contact with the polarizer with respect to the retardation film.

6. The laminate for a flexible image display device according to claim 5, wherein a transparent conductive layer forming a touch sensor is disposed on the side opposite to the surface in contact with the retardation film with respect to the second pressure-sensitive adhesive layer.

7. The laminate for a flexible image display device according to claim 6, wherein a third pressure-sensitive adhesive layer is disposed on the side opposite to the surface in contact with the second pressure-sensitive adhesive layer with respect to the transparent conductive layer forming a touch sensor.

8. The laminate for a flexible image display device according to claim 4, wherein a transparent conductive layer forming a touch sensor is disposed on the side opposite to the surface in contact with the protective film with respect to the first pressure-sensitive adhesive layer.

9. The laminate for a flexible image display device according to claim 8, wherein a third pressure-sensitive adhesive layer is disposed on the side opposite to the surface in contact with the first pressure-sensitive adhesive layer with respect to the transparent conductive layer forming a touch sensor.

10. A flexible image display device comprising the laminate for a flexible image display device according to claim 4 and an organic EL display panel, wherein the laminate for a flexible image display device is disposed on a viewing side with respect to the organic EL display panel.

11. The flexible image display device according to claim 10, wherein a window is disposed on a viewing side with respect to the laminate for a flexible image display device.
